(19) United States
(12) Patent Application Publication
(10) Pub. No.: US 2011/0045614 A1
(43) Pub. Date: Feb. 24, 2011

(54) Method and Apparatus for Providing LED Package with Controlled Color Temperature

(75) Inventors: Rene P. Helbing, Livermore, CA (US); Alexander Shaikevitch, Livermore, CA (US)

Correspondence Address: James M. Wu;JW Law Group, Suite 820, 84 West Santa Clara Street, San Jose, CA, 95113, US

(73) Assignee: BRIDGELUX, Inc., Livermore, CA (US)

(21) Appl. No.: 12/938,624

(22) Filed: Nov. 3, 2010

Related U.S. Application Data
(62) Division of application No. 12/323,924, filed on Nov. 26, 2008.

(51) Int. Cl. H01L 21/00

(52) U.S. Cl. 438/7; 29/25.01; 257/E21.001

(57) ABSTRACT

An optical device capable of illuminating visual light with adjusting color temperature after fabrication is disclosed. The optical device includes a solid state light emitter and a phosphor layer, which is formed over the solid state light emitter. The solid state light emitter, which can be a light emitter diode (“LED”), converts electrical energy to blue light. The phosphor layer subsequently converts first light with a first wavelength to second light with a second wavelength. In one example, the first light is blue light while the second light is white light. A portion of the phosphor layer is adjusted after the phosphor layer is formed for adjusting color of the white light in accordance with color quality of the light detected by a light detector.

### PRIORITY

This patent application is a divisional patent application of U.S. patent application Ser. No. 12/323,924, filed Nov. 26, 2008, entitled “Method and Apparatus for Providing LED Package with Controlled Color Temperature” by Rene Peter Helbing and Alexander Shaikevitch, the disclosure of which is incorporated herein by reference.

### FIELD

The exemplary aspect(s) of the present invention relates to lighting devices. More specifically, the aspect(s) of the present invention relates to manufacturing light-emitting devices based on semiconductor diodes using a transparent substrate.

### BACKGROUND

A light emitting diode (“LED”) is a lighting semiconductor device capable of converting electrical energy to light. With recent improvements in luminous output from an LED, conventional lighting apparatus such as incandescent light bulbs and/or fluorescent lamps are likely to be replaced with LEDs in the foreseeable future. Various commercial applications of LEDs, such as traffic lights, automobile lightings, and electronic billboards, have already been placed in service.

A conventional semiconductor package for an LED is typically fabricated with one or more phosphor layers and/or materials. The phosphor materials or layers are typically used to convert bluish radiation emitted from a semiconductor chip to brighter yellowish light with, for instance, yellowish wavelength. For example, a combination of blue light and yellow light may create warm and/or white natural light. The light color is typically measured by a standard measurement of color temperature. A resulting color temperature of an optoelectronic device is typically determined by the materials used as well as properties of phosphor materials. Properties of phosphor materials include specifics of phosphor formulation, concentration, as well as thickness of the phosphor layer.

A problem associated with a conventional LED fabrication technique for dispensing phosphor layers is that the fabrication process can create variations in physical dimension of each phosphor layer dispensed. Variations in physical dimension of phosphor layers result in variations in color temperature of the fabricated packages. Variations in color temperature of fabricated LED packages complicate a binning system, which adds additional steps in an inventory system for sorting LED packages according to different color temperatures.

A conventional approach to maintain color consistency across multiple LED devices or packages is to carefully pre-manufacture the conversion layer with controlled properties and subsequently join the conversion layer in an LED chip. A drawback for this conventional approach, however, is complexity and additional processing steps.

### SUMMARY

An optical device capable of illuminating visual light with adjusting light color after fabrication is disclosed. The optical device includes a solid state light emitter and a phosphor layer, which is formed over the solid state light emitter. The solid state light emitter, which can be a light emitter diode (“LED”) chip, converts electrical energy to light. The phosphor layer converts a first light having a first wavelength to a second light having a second wavelength. In one example, the first light is a blue light while the second light is a white light. A portion of the phosphor layer can be adjusted by a trimmer after the phosphor layer is formed for adjusting color of the white light in accordance with color quality of the light detected by a light detector.

Additional features and benefits of the exemplary aspect(s) of the present invention will become apparent from the detailed description, figures and claims set forth below.

### BRIEF DESCRIPTION OF THE DRAWINGS

The exemplary aspect(s) of the present invention will be understood more fully from the detailed description given below and from the accompanying drawings of various aspects of the invention, which, however, should not be taken to limit the invention to the specific aspects, but are for explanation and understanding only.

FIGS. 1(a-c) are cross-section views illustrating an optical device including a phosphor layer with controlled color temperature in accordance with an aspect of the present invention;

FIG. 2 illustrates a color temperature chart 200 showing a desirable correlated color temperature in accordance with an aspect of the present invention;

FIGS. 3(a-c) are cross-section views illustrating an optical device 300 capable of controlling color temperature in accordance with an aspect of the present invention;

FIGS. 4(a-c) are cross-section views illustrating an optical device including a phosphor layer with two colors in accordance with an aspect of the present invention;

FIG. 5 is a cross-section diagram illustrating an optical device having an adjustable warm phosphor layer in accordance with an aspect of the present invention;

FIG. 6 is a cross-section diagram illustrating a trimming device capable of trimming phosphor layer to adjust light color in accordance with an aspect of the present invention;

FIG. 7 illustrates an exemplary lighting device 700 having multiple solid state light emitters with controlled color temperature in accordance with an aspect of the present invention; and

FIG. 8 is a flowchart illustrating a process of adjusting light color of an optical device in accordance with an aspect of the present invention.

### DETAILED DESCRIPTION

Aspect(s) of the present invention is described herein in the context of a method, device, and apparatus of improving light color generated by an optical device with controlled color temperature.

Those of ordinary skills in the art will realize that the following detailed description of the exemplary aspect(s) is illustrative only and is not intended to be in any way limiting. Other aspects will readily suggest themselves to such skilled persons having the benefit of this disclosure. Reference will now be made in detail to implementations of the exemplary aspect(s) as illustrated in the accompanying drawings. The same reference indicators will be used throughout the drawings and the following detailed description to refer to the same or like parts.

In the interest of clarity, not all routine features of the implementations described herein are shown and described. It will, of course, be understood that in the development of any such actual implementation, numerous implementation-specific decisions may be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of this disclosure.

It is understood that an aspect of the present invention may contain integrated circuits that are readily manufacturable using conventional semiconductor technologies, such as, CMOS (complementary metal-oxide semiconductor) technology, MEMS (Micro-electromechanical systems) technology, or other semiconductor manufacturing processes. In addition, the aspect of the present invention may be implemented with other manufacturing processes for making optical as well as electrical devices.

An optical device capable of illuminating visual light with adjusting light color after fabrication is disclosed. The optical device includes a solid state light emitter and a phosphor layer, which is formed over the solid state light emitter. The solid state light emitter, which can be a light emitter diode (“LED”) chip, converts electrical energy to light, which may be a blue light. The solid state light emitter, in one aspect, provides light which can be visible light or invisible light. The phosphor layer subsequently converts a first light with a first wavelength to a second light with a second wavelength. In one example, the first light is blue light while the second light is white light. A portion of the phosphor layer is adjusted after the phosphor layer is formed for adjusting color of the white light in accordance with color quality of the light detected by a light detector.

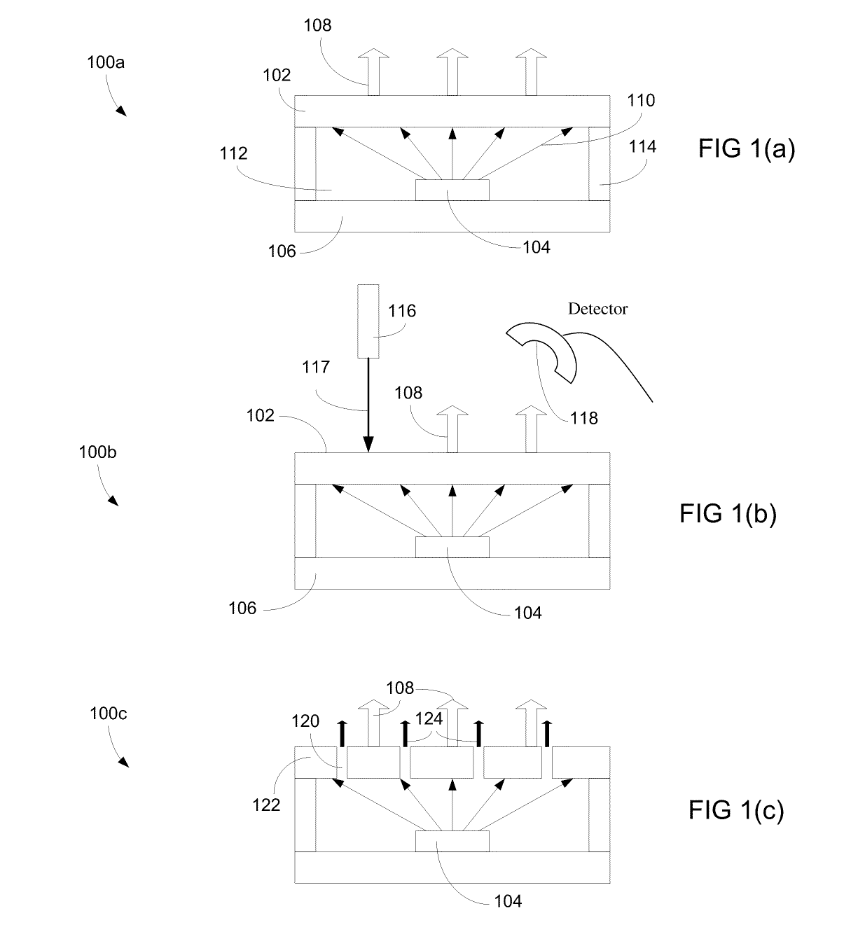

FIGS. 1(a-c) are cross-section views illustrating an optical device 100 including a phosphor layer with controlled color temperature in accordance with an aspect of the present invention. Device 100a, illustrated in FIG. 1(a), includes a substrate 106, a solid state light emitter 104, a phosphor layer 102, and dividers 114. In one aspect, device 100a includes a clear silicon layer 112 dispensed between solid state emitter 104 and phosphor layer 102 for light extracting. It should be noted that the underlying concept of the exemplary aspect(s) of the present invention would not change if one or more blocks (or layers) were added to or removed from device 100a.

Solid state light emitter 104, in an aspect, is a light emitter diode (“LED”) chip, wherein LED chip can further include gallium nitride layer(s), active layer, and indium tin oxide (“ITO”) layer for generating light. LED chip 104 is capable of producing light 110 when electrons and holes in the semiconductor materials are combined in accordance with quantum mechanics of biased p-n junction(s). Light 110, for instance, has a range of wavelengths between 400 and 475 nanometer (“nm”). When light 110 reaches phosphor layer 102, light 110 transforms from bluish light into white or yellowish light 108 when it passes through phosphor layer 102. The color of light 108 depends on composition of the phosphor layer, the thickness of phosphor layer, as well as the property of LED chip. Light 108, for instance, has a range of wavelengths between 440 and 650 nm. It should be noted that substance 112 can be either air or clear silicon for light extraction.

FIG. 1(b) illustrates a device 100b, a trimmer 116, and a light detector 118, wherein light detector 118 is capable of sensing or reading color of light 108. Trimmer 116 can be an adjustment instrument using various different technologies, such as a laser gun, metal scraper, micro-scalpel, chemical remover, photo etcher, or so forth. Trimmer 116, in one example, can be a laser instrument, which includes a laser beam 117. It should be noted that although FIG. 1(b) may include other component(s) or layers, other component(s) or layers not are necessary to understand the present aspect(s) of the invention.

During an operation, upon detecting white light 108, light detector 118 reports reading result to trimmer 116 indicating the detected color temperature or color quality. After comparing the reading result with predefined color temperature, trimmer 116 removes a portion of phosphor layer 102 in response to the result of the comparison. Trimmer 116 continues to trim phosphor layer 102 until a reading result matches with a predefined color temperature. It should be noted that color quality of cool light, visible light, blue light, red light, white light or the like can be measured by color temperature.

Color temperature is a chart characterizing a range of visible light such as lightings from light sources. The color temperature of a light source, for example, uses chromaticity to measure the light. Chromaticity identifies the quality of a color via its colorfulness and hue. It should be noted that other types of light color measurements such as color rendering index (“CRI”) may be used in place of color temperature for identifying the color quality.

FIG. 1(c) illustrates a device 100c after trimming in accordance with controlled color temperature. Multiple microscopic openings 120 have been created on phosphor layer 122 to adjust light color from yellowish to bluish. For example, blue light 124 emitted by LED chip 104 can pass through openings 120 without going through phosphor layer 122 whereby the combination of blue light 124 and yellowish light 108 changes the combined light from more yellowish to more bluish light. To achieve controlled color temperature, phosphor layer 122, in one aspect, is dispensed purposefully larger than minimal which is a necessary dimensional requirement for achieving a predefined color specification. In an alternative aspect, controlled color temperature can be achieved by adding substances such as phosphor materials on phosphor layer 102 or 122.

During fabrication of an LED device, a phosphor layer is produced with a thickness that is purposely larger than a minimum dimension for achieving a desirable color temperature. After fabrication, the phosphor layer is subsequently trimmed to create an LED package with specific and desirable color requirements. Laser trimming, which is similar to fabricating thick film passive components, may be used to trim phosphor layer(s). The laser is used to cut or drill microscopic holes into phosphor layer 122, thereby allowing more blue light to exit the package without passing through the phosphor layer 122. A mixture of additional blue light into the white light causes a shift of color from a warmer color to a colder color. As such, if a phosphor layer is fabricated or manufactured with a color temperature that is beyond the specification in the yellow color region, the color can be adjusted to a more desirable color region. The created microscopic holes are generally too small for human eyes to notice. The yellowish and bluish areas of the device can be blended to obtain desirable color(s). The trimming or adjusting process is monitored by a detector 118 and the process is terminated when the desirable color temperature is reached

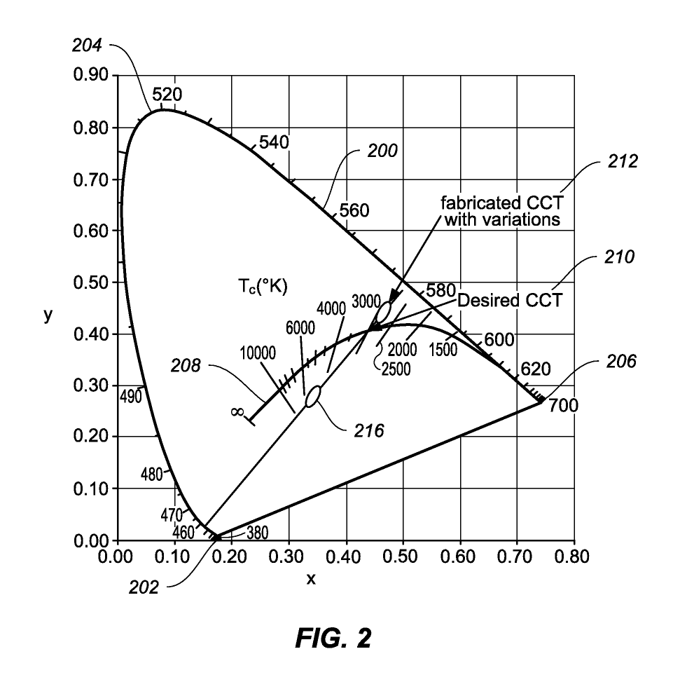

FIG. 2 illustrates a color temperature chart 200 showing a desirable correlated color temperature in accordance with an aspect of the present invention. Chart 200 illustrates a relationship between light color and its associated temperature. For example, match flame is approximately 1700 kelvin temperature (“° K”) while cool white light is approximately 3500° K. Chart 200 includes a blue region 202, a green region 204, a red region 206, and a temperature scale 208. Temperature scale 208 illustrates various lines showing correlated color temperature (“CCT”). An x-axis and a y-axis are used to show the chromaticity space associated with chart 200. For example, a white point, which may be a neutral reference characterized by a chromaticity, is approximately [0.3, 0.3] on the x-axis and y-axis of chromaticity space.

Chart 200 illustrates a desired CCT 210 and a fabricated CCT 212. In an aspect, after the device is fabricated, the light color of the device can be trimmed from fabricated CCT 212 to a desired CCT 210. It should be noted that the device or package is fabricated with a phosphor layer larger than a desire phosphor layer for the purpose of scaling back the phosphor layer after the fabrication of the phosphor layer. In an alternative aspect, if the fabricated device has lower CCT 216, the device can be adjusted to desired CCT 210 via adding phosphor substances on the phosphor layer.

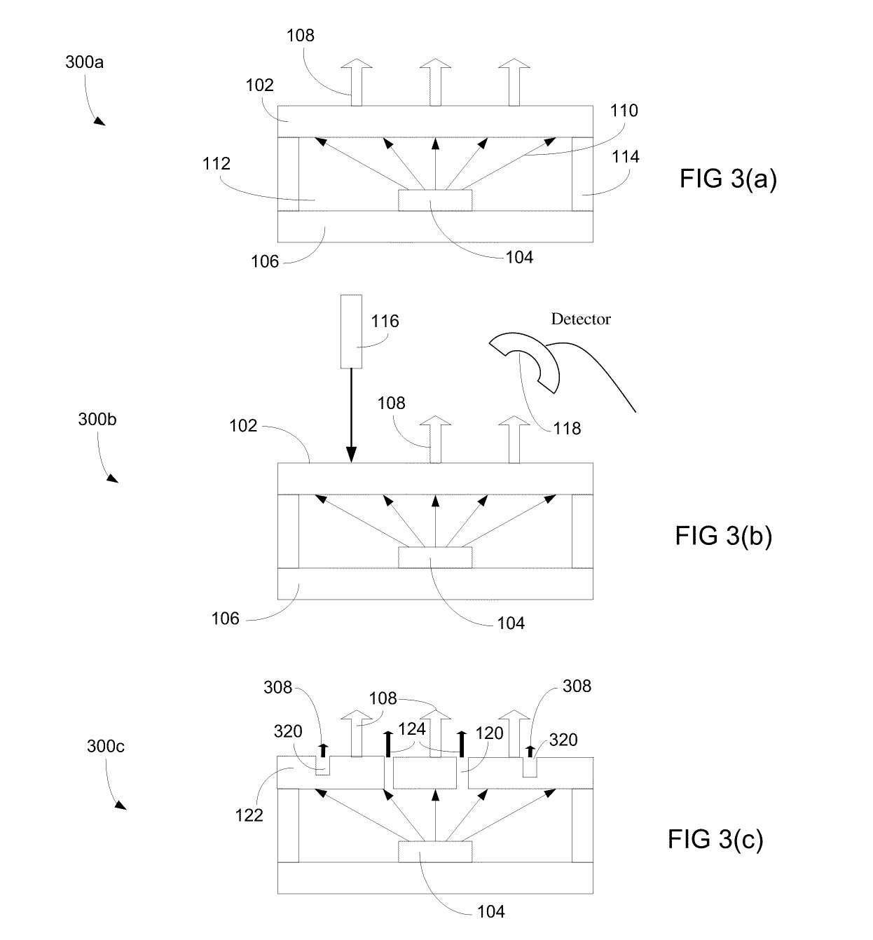

FIGS. 3(a-c) are cross-section views illustrating an optical device 300 capable of controlling color temperature in accordance with an aspect of the present invention. FIG. 3(a) shows a device 300a, which is similar to device 100a illustrated in FIG. 1(a), wherein device 300a includes a substrate 106, a solid state light emitter 104, a phosphor layer 102, and dividers 114. In one aspect, device 100 includes a clear silicon layer 112 dispensed between solid state emitter 104 and phosphor layer 102 for light extracting. It should be noted that the underlying concept of the exemplary aspect(s) of the present invention would not change if one or more blocks (or layers) were added to or removed from device 300.

FIG. 3(b) shows a device 300b, which is similar to device 100b illustrated in FIG. 1(b), and a trimmer 116, and a light detector 118. Light detector 118 is capable of sensing or reading color of light 106. Trimmer 116, in one example, can be a laser instrument including a laser beam 117.

FIG. 3(c) illustrates a device 300c after performance of trimming in accordance with controlled color temperature. In addition to microscopic openings 120 on phosphor layer 122, it also includes cavity 320 or multiple cavities used for adjusting light color 308 from yellowish to bluish. For example, upon obtaining a desirable color requirement, portions of phosphor layer 122 can be removed to comply with the desirable color requirement. A laser instrument 116 is used to create one or more cavities until the desirable color requirement or color temperature is reached. To achieve controlled color temperature, phosphor layer 122, in one aspect, is dispensed purposefully larger than minimal dimensional requirements for achieving the predefined color specifications. In an alternative aspect, controlled color temperature can be achieved by adding substances such as phosphor materials over a phosphor layer.

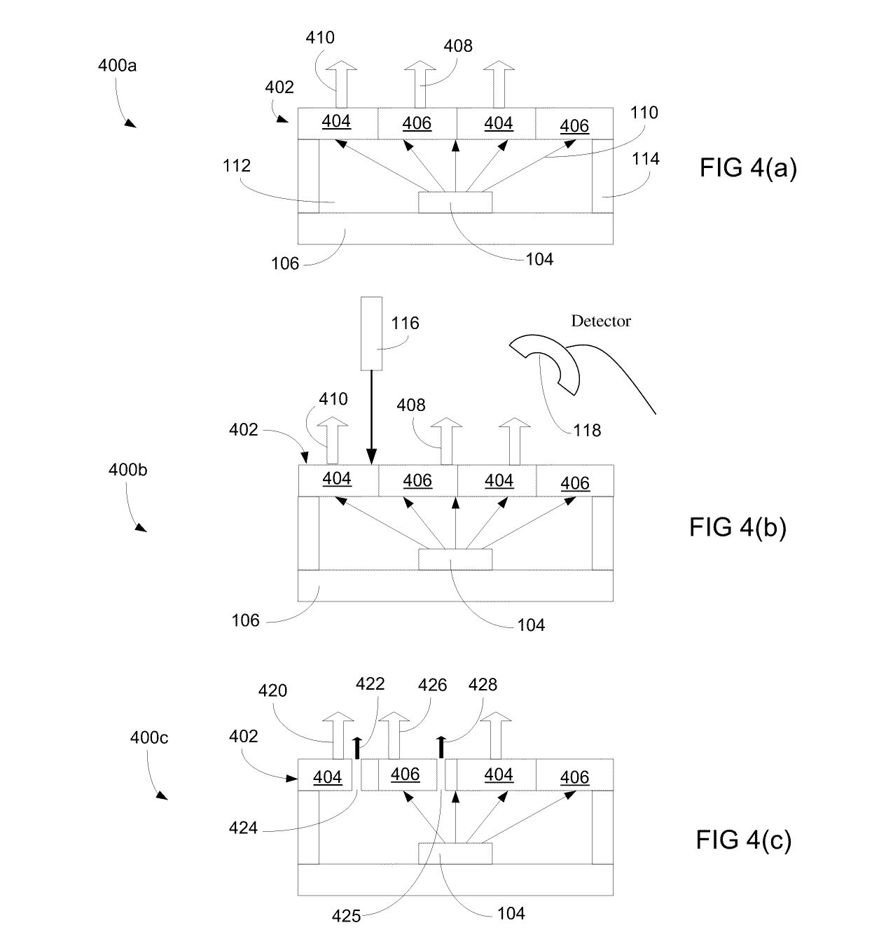

FIGS. 4(a-c) are cross-section views illustrating an optical device 400 including a phosphor layer having two colors in accordance with an aspect of the present invention. Device 400a, illustrated in FIG. 4(a), includes a substrate 106, a solid state light emitter 104, a phosphor layer 402, and dividers 114. In one aspect, device 400a includes a clear silicon layer 112 dispensed between solid state emitter 104 and phosphor layer 402 for light extracting. It should be noted that the underlying concept of the exemplary aspect(s) of the present invention would not change if one or more blocks (or layers) were added to or removed from device 400a.

Solid state light emitter 104, in an aspect, is a light emitter diode (“LED”) chip, wherein LED chip can further include gallium nitride layer(s), active layer, and indium tin oxide (“ITO”) layer for generating light. LED chip 104 is capable of producing light 110 when electrons and holes in the semiconductor materials are combined. When light 110 reaches phosphor layer 102, a portion of light 110 is transformed from bluish light into greenish light 410 while another portion of light 110 is transformed from bluish light to reddish light 408.

Phosphor layer 402, in an aspect, includes green sections 404 and red sections 406 wherein green sections 404 converts blue light 110 to yellowish green light 410 while red sections 406 converts blue light 110 to warm reddish light 408. When yellowish green light 410 merges with warm reddish light 408, the combination of lights 408 and 410, for example, generates natural white light. It should be noted that the color of light 408 or light 410 depends on the composition of the phosphor layer, the thickness of phosphor layer, as well as the property of the LED chip. It should be noted that substance 112 can be either air or clear silicon for light extracting.

FIG. 4(b) illustrates a device 400b, a trimmer 116, and a light detector 118, wherein light detector 118 is capable of sensing or reading color temperature of light 408. Trimmer 116 is an adjustment instrument using various different technologies, such as a laser, metal scraper, chemical remover, optical etcher, or the like. During an operation, upon detecting yellowish green light 410 and warm reddish light 408, light detector 118 reports the reading result to trimmer 116 indicating the detected color temperature of light 408. After comparing the reading result with predefined color temperatures, trimmer 116 removes a portion of phosphor layer 404 in response to the result of the comparison. Trimmer 116 continues to trim phosphor layer 402 until the reading result matches with the predefined color temperatures. It should be noted that the predefined color temperatures may indicate a range of colors.

FIG. 4(c) illustrates a device 400c after the performance of trimming in accordance with controlled color temperature. Multiple microscopic openings 424 and 425 have been created on phosphor layer 402 to adjust light color from yellowish to bluish light. For example, some blue light 428 emitted by LED chip 104 can pass through openings 425 without going through phosphor layer 406 whereby the combination of blue light 428 with yellowish green light 422 and warm reddish light 426 changes the combined light color from yellowish to bluish light. To achieve controlled color temperature, phosphor layer 402, in one aspect, is dispensed purposefully larger than minimal requirements for achieving the color specifications. In an alternative aspect, controlled color temperature can be achieved by adding substances such as phosphor materials on phosphor sections 404 and/or 406.

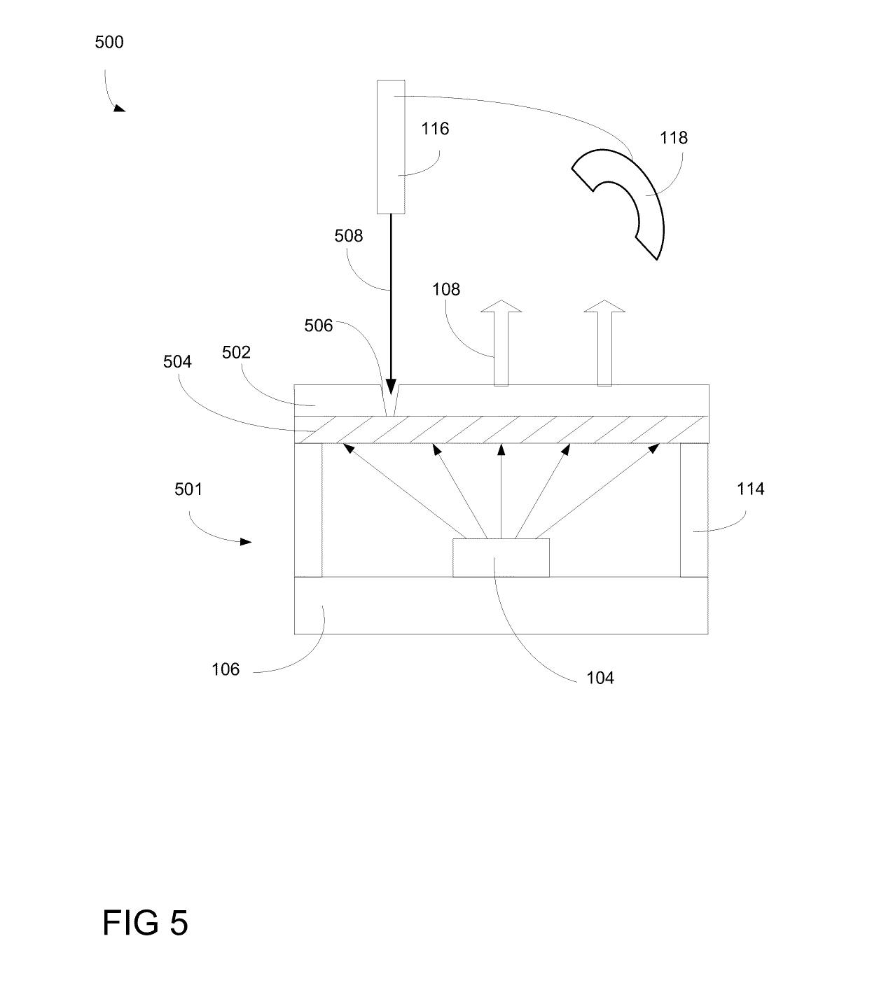

FIG. 5 is a cross-section diagram 500 illustrating an optical device having an adjustable warm phosphor layer in accordance with an aspect of the present invention. Diagram 500 includes an optical device 501, a trimming instrument 116, and a light detector 118. As illustrated in FIG. 1(b), instrument 116, which may be a laser trimmer, is capable of removing a portion of phosphor layer in response to color temperature detected by detector 118. It should be noted that the underlying concept of the exemplary aspect(s) of the present invention would not change if one or more blocks (or layers) were added to or removed from device 500.

Optical device 501 includes a substrate 106, a solid state light emitter 104, a first phosphor layer 504, a second phosphor layer 502, and dividers 114. In one aspect, device 501 includes an additional clear silicon layer dispensed between solid state emitter 104 and first phosphor layer 504. In an aspect, first phosphor layer 504 is a yellow phosphor layer while second phosphor layer 502 is a red phosphor layer. The yellow phosphor layer is used to convert the blue light emitted by solid state light emitter 104 to cool light, and red phosphor layer is used to convert the cool light to warm light. Depending on the properties of the red phosphor layer, the color temperature of device 501 can be different. In an alternative aspect, first phosphor layer 504 is a green phosphor layer while second phosphor layer 502 is an orange phosphor layer.

During fabrication of device 501, yellow phosphor layer 504 and red phosphor layer 502 are dispensed with thicknesses that are purposely larger than minimal dimensions of yellow and red phosphor layers for achieving a desirable range of color temperatures. After fabrication, the phosphor layers are subsequently trimmed to create a specific and desirable color light. Laser trimmer 116 is configured to remove a portion of phosphor layer via its laser beam 508. Laser beam 508 is capable of cut or drill microscopic holes 506 in the phosphor layer 502 thereby more cool light exits the package, which results a shift of reddish to yellowish light. As such, if a phosphor layer is fabricated or manufactured with a color temperature that is beyond the specification in the reddish color region, the color can be adjusted to a more desirable yellow color region. The trimming or adjusting process is monitored by detector 118, wherein the trimming process is stopped when a desirable color temperature is reached.

It should be noted that the trimming process of a referenced device or final device can be applied to one or multi-color patterns. It should be further noted that the trimming technique, which is combined with the process of screen printed dots with different phosphor materials (red and yellow) capable of adjusting color separately, can achieve even larger control over the final color temperature of the device.

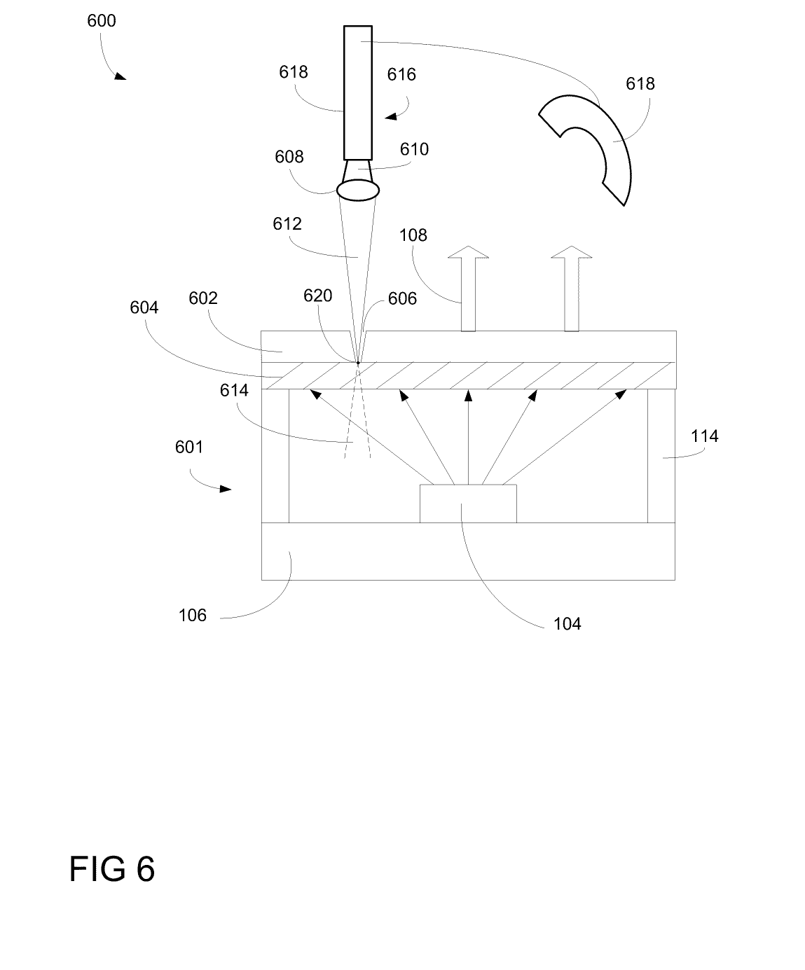

FIG. 6 is a cross-section diagram 600 illustrating a trimming device capable of trimming phosphor layer for adjusting light color in accordance with an aspect of the present invention. Diagram 600 includes an optical device 601, a trimming instrument 616, and a light detector 618. Device 601 is configured to perform similar functions as device 501 illustrated in FIG. 5, wherein device 601 includes a substrate 106, a solid state light emitter 104, a first phosphor layer 604, a second phosphor layer 602, and dividers 114. Similar to device 501, first phosphor layer 604 is a yellow or yellowish green phosphor layer while second phosphor layer 602 is a red or reddish orange phosphor layer. The yellow phosphor layer is used to convert the blue light emitted by solid state light emitter 104 to cool light, and red phosphor layer is used to convert the cool light to warm light.

Instrument 616, in one aspect, includes a body 618, a lens 608, and a lens holder 610. Lens 608, for example, is a biconvex lens, which is capable of converging a collimated beam to a converging beam 612. After traveling a focal distance, beam 612 converges to a point, which is also known as a focal point 620. The focal length is a distance between focal point 620 and the lens. Upon reaching focal point 620, light beam 612 diverges as it continues traveling. In an aspect, light beam 612 is capable of trimming phosphor layer up to focal point 620, and it loses its trimming capability once it travels beyond focal point 620. As such, the depth of trimming to a phosphor layer can be accurately controlled. For example, instrument 616 can be carefully calibrated to only trim the first layer while the second layer is intact. For example, to obtain cooler light, instrument 616 is calibrated to create openings 606 in first phosphor layer 602 while second phosphor layer 604 is intact.

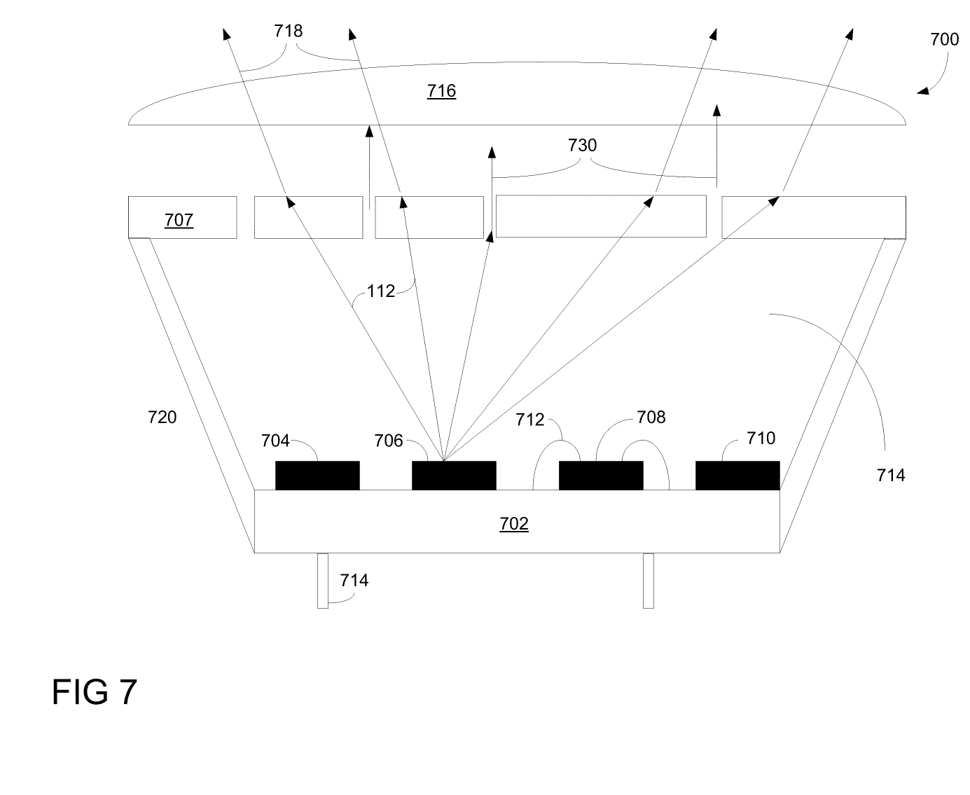

FIG. 7 illustrates an exemplary lighting device 700 having multiple solid state light emitters with controlled color temperature in accordance with an aspect of the present invention. Device 700 includes a substrate 702, four LEDs 704, 706, 708, or 710, a phosphor layer 707, a lens 716, and walls 720. Walls 720 are used to separate optical device 700 from other components such as neighboring optical devices. Walls 720 can also be a part of housing or cup configuration. Substrate 702, for example, is further coupled to a circuit board, not shown in FIG. 7, via coupling elements 714. It should be noted that the underlying concept of the exemplary aspect(s) of the present invention would not change if one or more blocks (or layers) were added to or removed from device 700.

In an aspect, device 700 includes multiple LEDs 704-710 wherein LEDs can be placed on substrate 702 via various connecting mechanisms such as wire bonds 712, solder balls, or conductive adhesions, not shown in FIG. 7. Phosphor layer 707 includes various microscopic openings or holes allowing blue light 730 to pass through phosphor layer 707 without conversion. An advantage of installing more than one LED in device 700 is to increase total luminous output. Lens 716 can be a glass, plastic, or silicon lens used for protecting phosphor layer 707 and device 700. In addition to providing device protection, lens 716 can provide a function of congregating light to form one or more light beams. It should be noted that additional layers or gas may be added between lens 716 and phosphor layer 707.

The exemplary aspect of the present invention includes various processing steps, which will be described below. The steps of the aspect may be embodied in machine or computer executable instructions. The instructions can be used to cause a general purpose or special purpose system, which is programmed with the instructions, to perform the steps of the exemplary aspect of the present invention. In another aspect, the steps of the exemplary aspect of the present invention may be performed by specific hardware components that contain hard-wired logic for performing the steps, or by any combination of programmed computer components and custom hardware components.

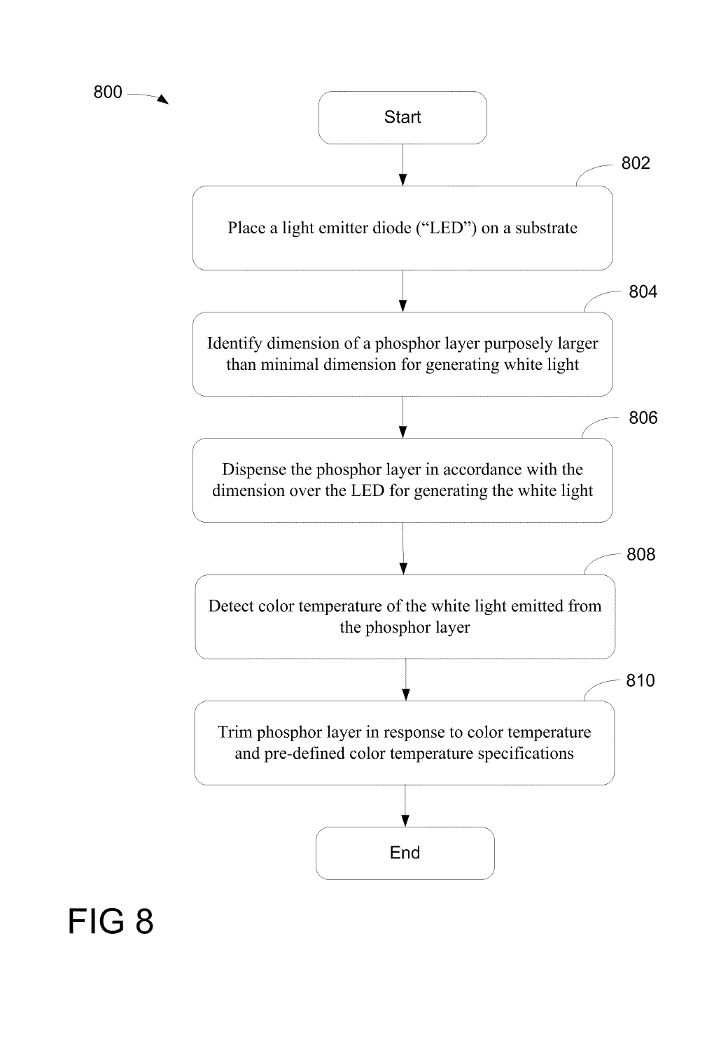

FIG. 8 is a flowchart illustrating a process of adjusting light color of an optical device in accordance with an aspect of the present invention. At block 802, a process places a light emitter diode (“LED”) on a substrate. In an aspect, the process is capable of facilitating the LED to convert electrical energy to blue light. In another aspect, the process dispenses a silicone layer over the LED for extracting light from the LED.

At block 804, the process identifies a dimension of a phosphor layer, wherein the dimension is purposely larger than minimal dimension required for a phosphor layer to generate white light in accordance with a predefined color temperature. In an aspect, the process is capable of determining adequate length, width, and thickness of a phosphor layer in response the predefined color temperature.

At block 806, the process dispenses a phosphor layer in accordance with the dimension over the LED for generating white light. For one example, the process is capable of dispensing a dome shaped light extracting layer over the LED for extracting the blue light and dispensing the phosphor layer over the dome shaped light extracting layer.

At block 808, the process detects color temperature of the white light emitted from the phosphor layer. In an aspect, the process is further capable of comparing the color temperature detected from the white light with the predefined color temperatures.

At block 810, the process trims the phosphor layer in response to the color temperature detected and the predefined color temperatures. In an aspect, the process removes a portion of the phosphor layer in response to a result of comparison between the color temperature detected from the white light and the predefined color temperatures. For example, the process is also capable of creating at least one cavity on the phosphor layer to adjust light color in accordance with the predefined color temperatures. The process, for instance, sets a cavity diameter ranging from 50 micrometers to 1 millimeter. In an alternative aspect, the process is capable of trimming a red phosphor layer to adjust warm light in response to the predefined color temperatures.

While particular aspects of the present invention have been shown and described, it will be obvious to those ordinary skilled in the art that, based upon the teachings herein, changes and modifications may be made without departing from this exemplary aspect(s) of the present invention and its broader aspects. Therefore, the appended claims are intended to encompass within their scope all such changes and modifications as are within the true spirit and scope of this exemplary aspect(s) of the present invention.

What is claimed is:

1. A method for manufacturing a lighting device, comprising:
placing a light emitter diode (“LED”) on a substrate;
identifying a dimension of a phosphor layer purposely larger than minimal dimension of the phosphor layer for generating white light in accordance with a predefined color temperature;
dispensing the phosphor layer in accordance with the dimension over the LED for generating the white light;
detecting color temperature of the white light emitted from the phosphor layer; and
trimming the phosphor layer in response to the color temperature and the predefined color temperature.

2. The method of claim 1, further comprising dispensing a silicone layer over the LED for extracting light from the LED.

3. The method of claim 1, wherein placing a light emitter diode (“LED”) on a substrate includes facilitating the LED to convert electrical energy to light.

4. The method of claim 1, wherein identifying dimension of a phosphor layer purposely larger than minimal dimensions for generating white light includes determining adequate length, width, and thickness of the phosphor layer in response the predefined color temperatures.

5. The method of claim 1, wherein dispensing the phosphor layer in accordance with the dimension over the LED further includes:
dispensing a dome shaped light extracting layer over the LED for extracting the light; and
dispensing the phosphor layer over the dome shaped light extracting layer.

6. The method of claim 1, wherein detecting color temperature of the white light emitted from the phosphor layer includes comparing the color temperature detected from the white light with the predefined color temperatures.

7. The method of claim 1, wherein trimming the phosphor layer in response to the color temperature and the predefined color temperatures includes removing a portion of the phosphor layer in response to a result of comparison between the color temperature detected from the white light and the predefined color temperatures.

8. The method of claim 7, wherein removing a portion of the phosphor layer in response to a result of comparison between the color temperature detected from the white light and the predefined color temperatures further includes creating at least one cavity on the phosphor layer to adjust light color in accordance with the predefined color temperatures.

9. The method of claim 8, wherein creating at least one cavity on the phosphor layer to adjust light color in accordance with the predefined color temperatures further includes setting a cavity diameter ranging from 50 micrometers to 1 millimeter.

10. The method of claim 1, further comprising trimming a red phosphor layer to adjust warm light in response to the predefined color temperatures.

11. An apparatus for manufacturing a lighting device, comprising:
means for placing a light emitter diode (“LED”) on a substrate;
means for identifying dimension of a phosphor layer purposely larger than minimal dimension for generating white light in accordance with a predefined color temperatures;
means for dispensing the phosphor layer in accordance with the dimension over the LED for generating the white light;
means for detecting color temperature of the white light emitted from the phosphor layer; and
means for trimming the phosphor layer in response to the color temperature and the predefined color temperature.

12. The apparatus of claim 11, further comprising means for dispensing a silicone layer over the LED for extracting light from the LED.

13. The apparatus of claim 11, wherein means for trimming the phosphor layer in response to the color temperature and the predefined color temperatures includes means for removing a portion of the phosphor layer in response to a result of comparison between the color temperature detected from the white light and the predefined color temperatures.

14. The apparatus of claim 11, wherein means for placing a light emitter diode (“LED”) on a substrate includes means for facilitating the LED to convert electrical energy to light.

15. The apparatus of claim 11, wherein means for identifying dimension of a phosphor layer purposely larger than minimal dimensions for generating white light includes means for determining adequate length, width, and thickness of the phosphor layer in response the predefined color temperatures.

16. The apparatus of claim 11, wherein means for dispensing the phosphor layer in accordance with the dimension over the LED further includes:
means for dispensing a dome shaped light extracting layer over the LED for extracting the light; and
means for dispensing the phosphor layer over the dome shaped light extracting layer.

17. The apparatus of claim 11, wherein means for detecting color temperature of the white light emitted from the phosphor layer includes means for comparing the color temperature detected from the white light with the predefined color temperatures.
